(19) United States
(12) Patent Application Publication
(10) Pub. No.: US 2010/0308397 A1
(43) Pub. Date: Dec. 9, 2010

(54) SEMICONDUCTOR DEVICE AND METHOD FOR MANUFACTURING THE SAME

(75) Inventor: Junichi Ariyoshi, Yokohama (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: Fujitsu Semiconductor Limited, Yokohama-shi (JP)

(21) Appl. No.: 12/791,990

(22) Filed: Jun. 2, 2010

(30) Foreign Application Priority Data
Jun. 3, 2009 (JP) 2009-133746

(51) Int. Cl. H01L 29/792; H01L 21/8234

(52) U.S. Cl. 257/324; 438/238; 257/E21.616; 257/E29.309

(57) ABSTRACT

A method for manufacturing a semiconductor device includes forming an insulating film on a semiconductor region of a semiconductor substrate on which a MOS transistor is to be formed and patterning the insulating film; implanting an impurity into the semiconductor region through the patterned insulating film using a step of implanting an impurity into a source/drain region of the MOS transistor, to form, below the insulating film, a resistive layer of a resistance element to be formed in the semiconductor region; and siliciding a surface of the source/drain region of the MOS transistor using the insulating film as a silicidation-preventing film of the resistive layer.

### CROSS-REFERENCE TO RELATED APPLICATIONS

This application is based upon and claims the benefit of priority of the prior Japanese Patent Application No. 2009-133746, filed on Jun. 3, 2009 the entire contents of which are incorporated herein by reference.

### FIELD

The present invention relates to a semiconductor device including a resistance element and a method for manufacturing the same.

### BACKGROUND

In recent years, semiconductor devices with various functions, such as memory-merged integrated circuits, have been widely used. In general, such semiconductor devices include passive elements such as a resistor and a capacitor on the substrate on which active elements such as a transistor are disposed. In particular, a resistance element is used in a control circuit, a power supply circuit, a protection circuit, and various circuits having other functions.

A resistance element is generally formed in a semiconductor substrate on which a transistor and the like are formed or in a semiconductor film formed on a semiconductor substrate and made of, for example, polysilicon.

In silicon semiconductor devices including, for example, a MOS transistor, the surfaces of a silicon semiconductor substrate and a polysilicon film or the like formed on the silicon semiconductor substrate are normally silicided to decrease the resistances of the source, drain, and gate electrodes. Thus, to form a resistance element having a desired resistance value, a semiconductor substrate or a semiconductor film that is to be a resistive layer is typically prevented from being silicided with transistor electrodes.

Furthermore, when a resistance element is formed, it is desirable to decrease the number of additional steps of forming the resistance element. There has been known a method for forming a resistive layer of a resistance element using ion implantation performed on an extension region of a MOS transistor, that is, a lightly doped drain (LDD) region. In this method, a resistive layer is formed by the above-described ion implantation, and a so-called silicide block, which is a film that prevents silicidation, is then formed on the resistive layer. Subsequently, an electrode region of the resistance element is formed by ion implantation using the silicide block as a mask.

The method in which a resistive layer of a resistance element is formed using ion implantation performed on an extension region of a MOS transistor poses a problem in that the range of choices of a resistance value to be obtained is limited. In other words, since the ion concentration of ion implantation performed on an extension region affects the characteristics of the MOS transistor, it is not possible to change the ion concentration of the ion implantation in accordance with the requirement for a resistance element, which poses a problem in that the degree of freedom for selecting a resistance value of the resistance element is limited. Furthermore, a silicide block is typically formed in the region of the resistance element using an additional mask after the formation of the resistive layer. This causes difficulty in decreasing the number of additional steps of forming the resistance element.

### SUMMARY

According to one aspect of the invention, a method for manufacturing a semiconductor device includes forming an insulating film on a semiconductor region of a semiconductor substrate on which a MOS transistor is to be formed and patterning the insulating film; implanting an impurity into the semiconductor region through the patterned insulating film using a step of implanting an impurity into a source/drain region of the MOS transistor, to form, below the insulating film, a resistive layer of a resistance element to be formed in the semiconductor region; and siliciding a surface of the source/drain region of the MOS transistor using the insulating film as a silicidation-preventing film of the resistive layer.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a sectional view illustrating a semiconductor device according to a first embodiment;

FIGS. 2A to 2D are sectional views illustrating a method for manufacturing the semiconductor device of FIG. 1;

FIG. 3 is a sectional view illustrating a semiconductor device according to a second embodiment;

FIGS. 4A to 4O are sectional views illustrating a method for manufacturing the semiconductor device of FIG. 3;

FIG. 5 is a sectional view illustrating a semiconductor device according to a third embodiment; and

FIGS. 6A to 6O are sectional views illustrating a method for manufacturing the semiconductor device of FIG. 5.

### DETAILED DESCRIPTION OF THE EMBODIMENTS

Embodiments will now be described in detail with reference to the attached drawings. Throughout the drawings, the same or corresponding elements are designated by the same or similar reference numerals.

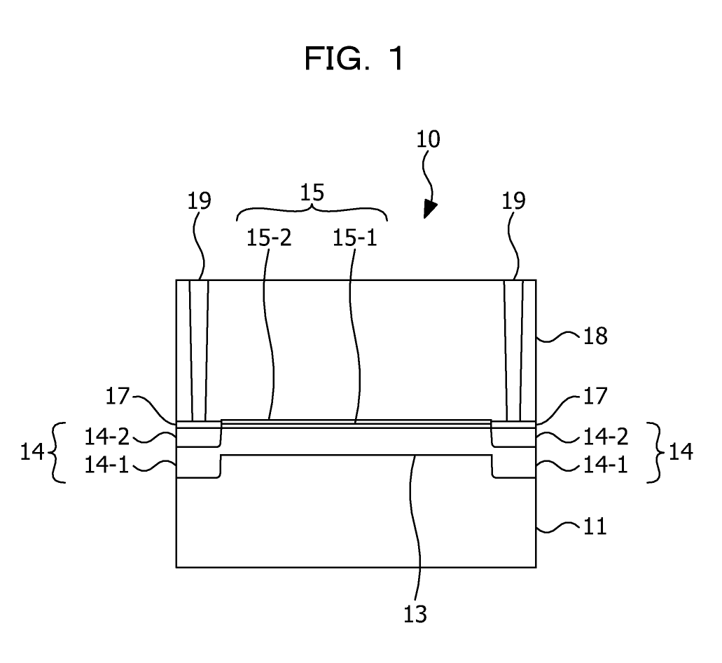

A semiconductor device according to a first embodiment is described with reference to FIG. 1. The semiconductor device includes a resistance element 10. The resistance element 10 is formed on a surface of a semiconductor region 11. The semiconductor region 11 is, for example, part of a semiconductor substrate such as a silicon (Si) wafer. However, the resistance element according to this embodiment is not necessarily formed on a wafer surface, and may be formed in a semiconductor film made of, for example, polycrystalline silicon, amorphous silicon, or crystalline silicon, the semiconductor film being formed on a wafer surface.

The resistance element 10 includes a resistive layer 13 formed in a Si wafer (in the semiconductor region 11), an electrode region 14 adjacent to the resistive layer 13, an insulating film 15 formed on the resistive layer 13, and a silicide film 17 formed on the electrode region 14. The resistance element 10 further includes an interlayer insulating film 18 covering the resistance element and an electrode contact 19 formed in the interlayer insulating film 18.

In FIG. 1, the electrode region 14 includes a first electrode layer 14-1 and a second electrode layer 14-2 contained in the first electrode layer 14-1. As described below, the resistive layer 13 and the electrode layers 14-1 and 14-2 are impurity-diffused regions each formed by implanting an impurity into the Si wafer and activating the impurity. Each of the regions has an impurity of the same conductivity type (n-type or p-type). The electrode layer 14-2 has an impurity having a higher concentration than that of the electrode layer 14-1 to form the silicide film 17 and to allow the electrode region 14 to function as a low-resistance electrode of the resistance element 10 in the depth direction thereof. The insulating film 15 includes, for example, a silicon oxide film 15-1 formed on a surface of the Si wafer and a silicon nitride film 15-2 formed on the silicon oxide film 15-1. For example, the silicon oxide film 15-1 has a thickness of 9 to 14 nm and the silicon nitride film 15-2 has a thickness of 3 to 7 nm. The insulating film 15 may include simply a silicon oxide film, simply a silicon nitride film, a so-called “ONO film” having silicon oxide film/silicon nitride film/silicon oxide film, or a film made of a different insulating material in accordance with the structure of the entire semiconductor device. The silicide film 17 is made of a silicide of a high-melting point metal such as cobalt (Co), titanium (Ti), or tungsten (W).

In FIG. 1, the resistive layer 13 and the electrode layer 14-1 are formed using the same ion implantation step of performing ion implantation through the insulating film 15. Because of the presence of the insulating film 15, the resistive layer 13 is formed at a position shallower than that of the electrode layer 14-1 with respect to the surface of the Si wafer. That is, the insulating film 15 controls the depth to which an impurity is implanted in the Si wafer and allows the resistive layer 13 to be formed directly below the insulating film 15 at a position shallower than that of the electrode layer 14-1. The insulating film 15 further functions as a mask for preventing an impurity from being implanted into the resistive layer 13 in the ion implantation step of forming the electrode layer 14-2. Thus, the sheet resistance of the resistive layer 13 is mainly controlled in accordance with the thickness of the insulating film 15 and the acceleration energy and dosage in the ion implantation step of forming the resistive layer 13 and the electrode layer 14-1. However, part of the impurity implanted in the ion implantation step of forming the electrode layer 14-2 may be implanted into the resistive layer 13. The electrode region 14 does not always include two layers illustrated in FIG. 1, and may include at least three layers or a single layer. However, the electrode region 14 preferably includes at least two layers to independently control a resistance value of the resistive layer 13 and the characteristics of the electrode region 14 such as low resistivity.

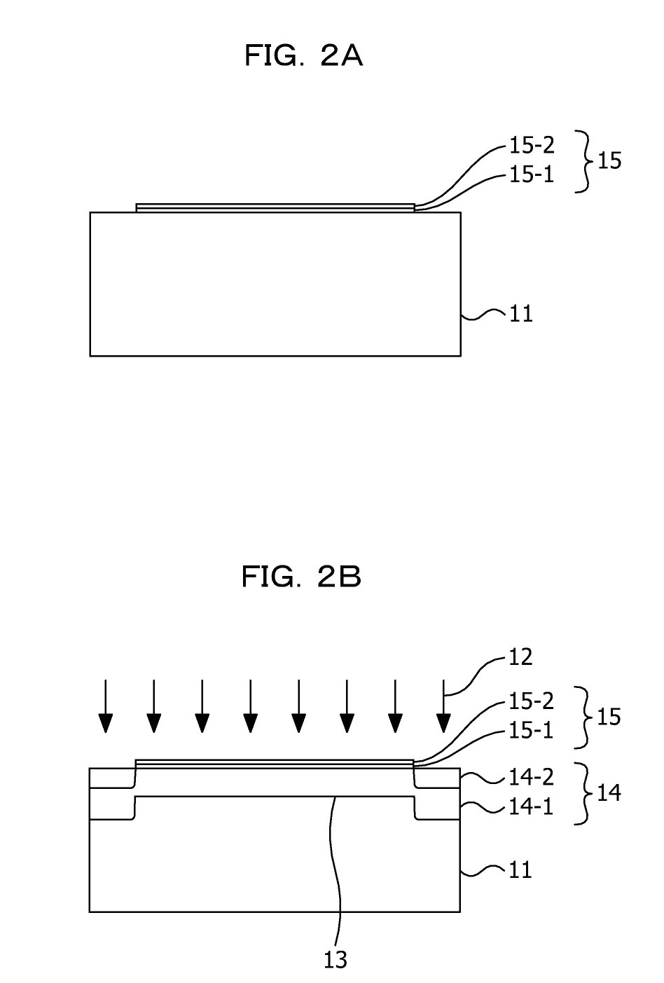

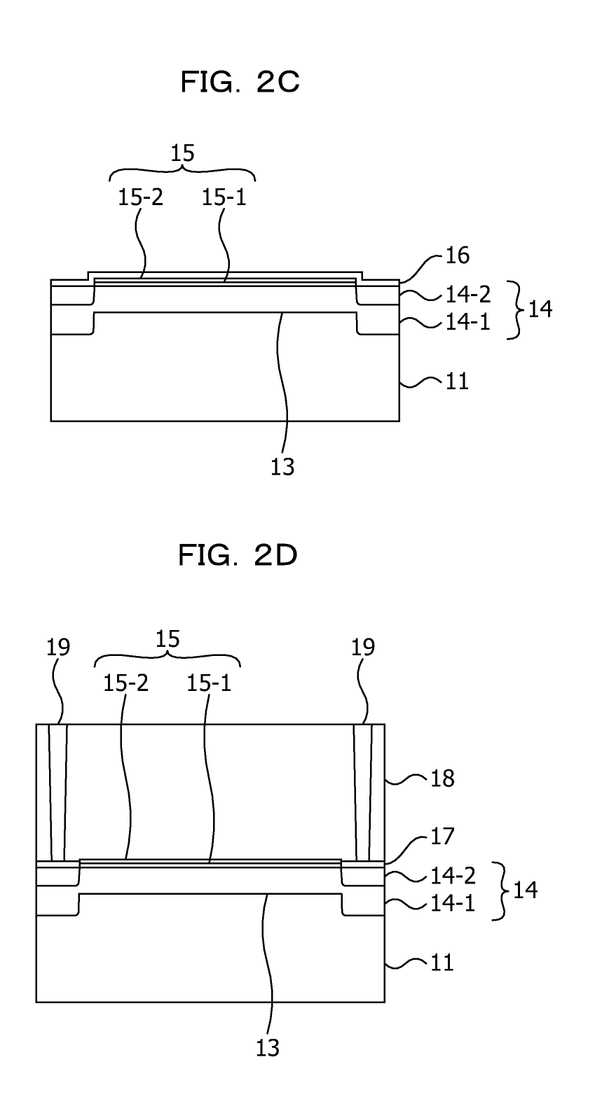

A method for manufacturing the semiconductor device illustrated in FIG. 1 will now be described with reference to FIGS. 2A to 2D.

As illustrated in FIG. 2A, an insulating film is formed on a semiconductor region 11 in a Si wafer, a semiconductor film, or the like. An insulating film 15 is left in a region where a resistive layer is to be formed, by photolithography and etching. In this case, the insulating film 15 includes a silicon oxide film 15-1 and a silicon nitride film 15-2. The thicknesses of the silicon oxide film 15-1 and the silicon nitride film 15-2 are, for example, 11.5 nm and 5 nm, respectively, and determine the depth to which an impurity is to be implanted in the semiconductor region 11 in the ion implantation step to be performed through the insulating film 15.

As illustrated in FIG. 2B, ion implantation 12 is performed using an n-type impurity or a p-type impurity such that the impurity is implanted into a semiconductor substrate or semiconductor film 11 through the insulating film 15. The ion implantation 12 is performed twice in different conditions. Preferably, an impurity for forming the resistive layer 13 and the electrode layer 14-1 is implanted in a first ion implantation step and an impurity for forming the electrode layer 14-2 is implanted in a second ion implantation step. Thus, the acceleration energy in the second ion implantation step is set to be lower than that in the first ion implantation step. The dosage in the second ion implantation step is set to be higher than that in the first ion implantation step to obtain the electrode layer 14-2 as a diffusion layer having a concentration higher than that of the electrode layer 14-1.

When an n-type diffusion resistance element is formed, an n-type impurity (donor) such as phosphorus or arsenic is implanted during the ion implantation 12. For example, when the silicon oxide film 15-1 and the silicon nitride film 15-2 each have the above-described thickness, phosphorus is implanted at an energy of 15 keV in the first ion implantation step and phosphorus is implanted at an energy of 8 keV in the second ion implantation step. The dosage in the first ion implantation step is determined such that a desired sheet resistance of the resistive layer 13 is obtained and is not particularly limited. If the desired sheet resistance is 200 Ω/sq, the dosage is about 8.0×10¹³ cm⁻². If the desired sheet resistance is 800 Ω/sq, the dosage is about 1.0×10¹³ cm⁻². The dosage in the second ion implantation step is, for example, 1.2×10¹⁶ cm⁻².

When a p-type diffusion resistance element is formed, a p-type impurity (acceptor) such as boron is implanted during the ion implantation 12. For example, when the silicon oxide film 15-1 and the silicon nitride film 15-2 each have the above-described thickness, boron is implanted at an energy of 8 keV in the first ion implantation step and boron is implanted at an energy of 4 keV in the second ion implantation step. The dosage in the first ion implantation step is not particularly limited. If the desired sheet resistance is 300 Ω/sq, the dosage is about 9.0×10¹³ cm⁻². If the desired sheet resistance is 900 Ω/sq, the dosage is about 7.0×10¹² cm⁻². The dosage in the second ion implantation step is, for example, 6.0×10¹⁵ cm⁻².

Thus, part of the dosage desired for the electrode region 14 is selectively implanted into the resistive layer 13 due to the presence of the insulating film 15 and its thickness. In a step following the ion implantation 12 or in a step performed later, heat treatment is performed to activate the implanted impurity.

As illustrated in FIG. 2C, a metal film 16 made of a high-melting point metal such as cobalt, titanium, or tungsten is formed on the entire surface of the semiconductor region 11 by sputtering or the like.

As illustrated in FIG. 2D, heat treatment is performed, for example, in a nitrogen atmosphere, whereby a silicidation reaction is caused in an exposed portion of the semiconductor region 11, that is, between the electrode region 14 and the metal film 16 to form a silicide film 17 on a surface of the electrode region 14 in a self-aligning manner. Herein, the resistive layer 13 is not silicided because it is covered with the insulating film 15, and thus the resistance is not decreased. Subsequently, by removing an unreacted metal film 16, forming an interlayer insulating film 18, patterning the interlayer insulating film 18, and embedding an electrode contact 19, a structure of the semiconductor device illustrated in FIG. 1 is obtained.

In the first embodiment, the insulating film 15 is formed before the ion implantation 12 for forming the resistive layer 13. The insulating film 15 allows the resistive layer 13 and the electrode region 14 of the resistance element 10 to be simultaneously formed through a single ion implantation step (as described above, ion implantation may be performed multiple times at different energies and/or dosages). The insulating film 15 also controls the amount of the impurity implanted into the semiconductor region 11 through the single ion implantation step in accordance with the thickness thereof. This extends the range of choices of a resistance value of the resistance element. The insulating film 15 also functions as a silicide block for the resistive layer 13. As a result, there is no need to form an additional silicide block after the formation of the resistive layer 13.

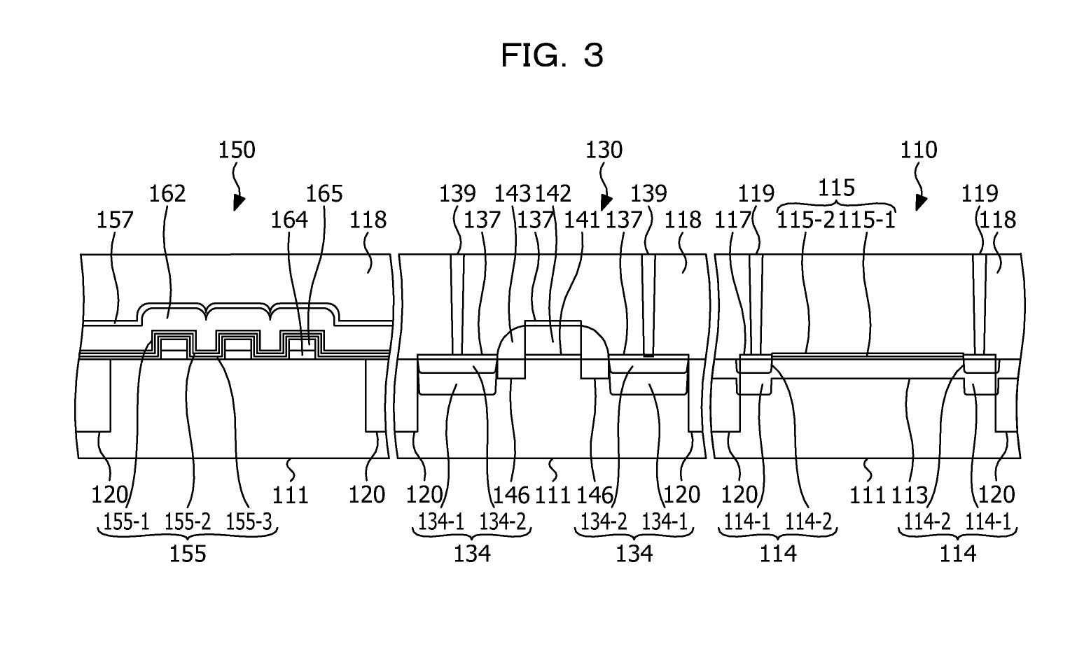

A semiconductor device according to a second embodiment will now be described with reference to FIG. 3. The semiconductor device includes a resistance element 110, a MOS transistor 130, and optionally a memory element 150. The resistance element 110, the MOS transistor 130, and the memory element 150 are formed on a semiconductor substrate 111, which is a Si wafer herein, and separated from one another through an element-separating insulating film 120. The Si wafer 111 may be a p-type wafer or an n-type wafer. A p-type well or an n-type well may be formed in each of the regions separated through the element-separating insulating film 120 in accordance with the polarity of an element to be formed.

The resistance element 110 has the same structure as that of the resistance element 10 illustrated in FIG. 1 and is described as an n-type diffusion resistance element unless otherwise specified.

The MOS transistor 130 is one of transistors that make up a logic circuit or the like and is either a p-channel metal-oxide semiconductor (PMOS) transistor or an n-channel metal-oxide semiconductor (NMOS) transistor. Herein, the MOS transistor 130 is described as an NMOS transistor formed in a p-type silicon region (substrate or well) unless otherwise specified.

The NMOS transistor 130 includes an n-doped source/drain region 134, a gate insulating film 141, and a gate electrode 142. A side wall 143 separating the gate electrode 142 from the source/drain region 134 is formed on the side of the gate electrode 142. An extension region of the source/drain region 134, that is, an LDD region 146 is formed below the side wall 143. A silicide film 137 is formed on an upper surface of each of the source/drain region 134 and the gate electrode 142. The NMOS transistor 130 further includes an interlayer insulating film 118 covering the NMOS transistor and a source/drain contact 139 formed in the interlayer insulating film 118.

For example, the gate insulating film 141 is a silicon oxide film and the gate electrode 142 is a doped polysilicon electrode. However, the materials of the gate insulating film 141 and the gate electrode 142 are not particularly limited. The gate insulating film 141 may be a gate insulating film including, for example, a silicon nitride film or a high dielectric film. The gate electrode 142 may be a gate electrode including a metal film. The side wall 143 is preferably made of a material such as silicon oxide.

In FIG. 3, the source/drain region 134 of the NMOS transistor 130 includes a first source/drain region 134-1 and a second source/drain region 134-2 contained in the first source/drain region 134-1, both of which are n-doped. The first source/drain region 134-1 and the second source/drain region 134-2 of the NMOS transistor 130 have substantially the same diffusion depth and impurity concentration as those of a first electrode layer 114-1 and a second electrode layer 114-2 of the n-type diffusion resistance element 110, respectively.

The silicide film 137 formed on the source/drain region 134 and the gate electrode 142 of the MOS transistor 130 is made of a silicide of the same high-melting point metal as that of a silicide film 117 formed on an electrode region 114 of the resistance element 110.

The memory element 150 is a memory element that makes up a memory element array of a memory-merged integrated circuit. In this case, the memory element 150 has a floating gate type memory cell such as a flash memory. FIG. 3 illustrates the memory element 150 at a section taken along a single word line.

In FIG. 3, the memory element 150 is formed in a p-type silicon region (substrate or well) and includes a floating gate 165 and a control gate 162. The memory element 150 also includes a tunnel insulating film 164 formed between the Si wafer 111 and the floating gate 165 and an intergate insulating film 155 formed between the semiconductor substrate 111 and the control gate 162 and between the floating gate 165 and the control gate 162. The memory element 150 also includes a silicide film 157 formed on an upper surface of the control gate 162, an interlayer insulating film 118 covering the memory element, and a contact formed in the interlayer insulating film 118 at another section (not illustrated) of the memory element.

The floating gate 165 stores electrons injected through the tunnel insulating film 164, which is typically a silicon oxide film. The control gate 162 is part of a word line. The floating gate 165 and the control gate 162 are each made of polysilicon. The control gate 162 is preferably made of the same material as that of the gate electrode 142 of the MOS transistor 130. The intergate insulating film 155 is, for example, an ONO film including a silicon oxide film 155-1, a silicon nitride film 155-2, and a silicon oxide film 155-3. The silicon oxide film 155-1 and the silicon nitride film 155-2 of the intergate insulating film 155 preferably have the same compositions as those of a silicon oxide film 115-1 and a silicon nitride film 115-2 of an insulating film 115 of the resistance element 110, respectively. Furthermore, the silicide film 157 of the memory element 150 is preferably made of a silicide of the same high-melting point metal as that of the silicide film 117 of the resistance element 110 and the silicide film 137 of the MOS transistor 130.

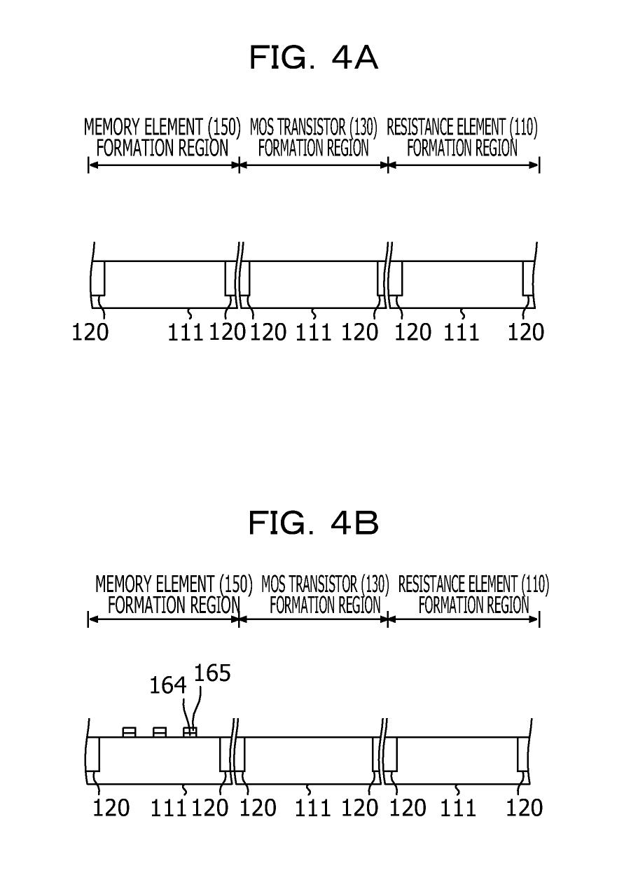

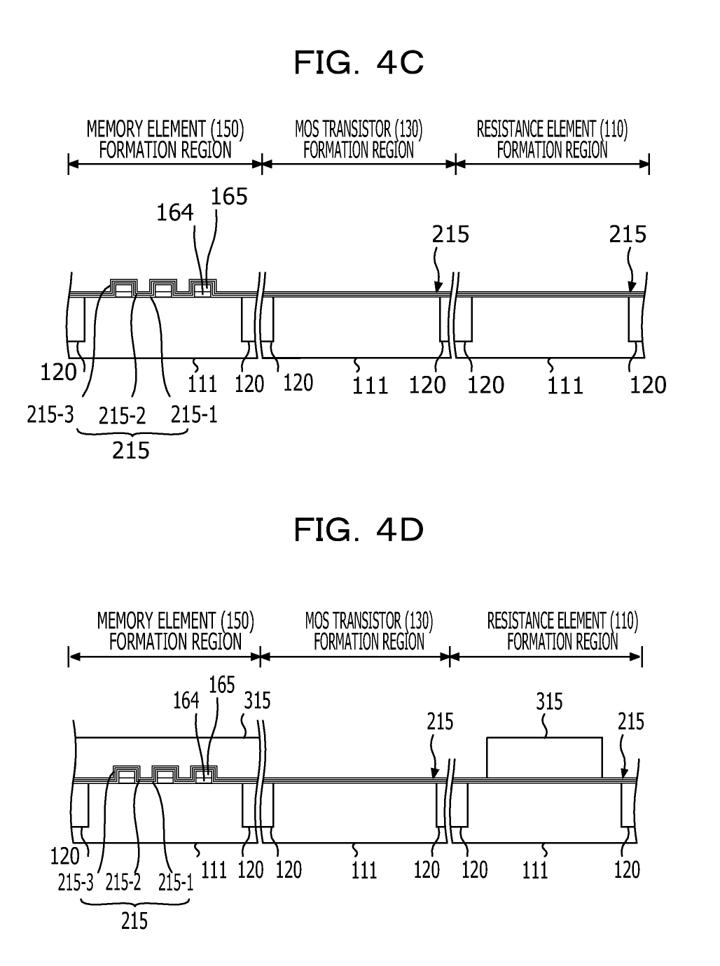

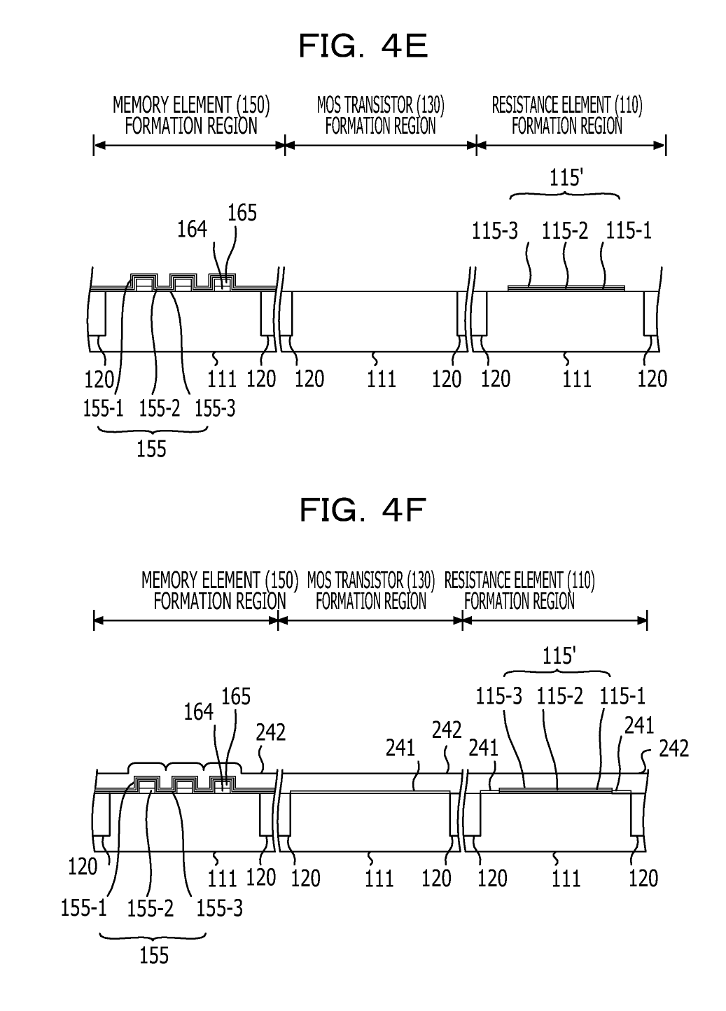

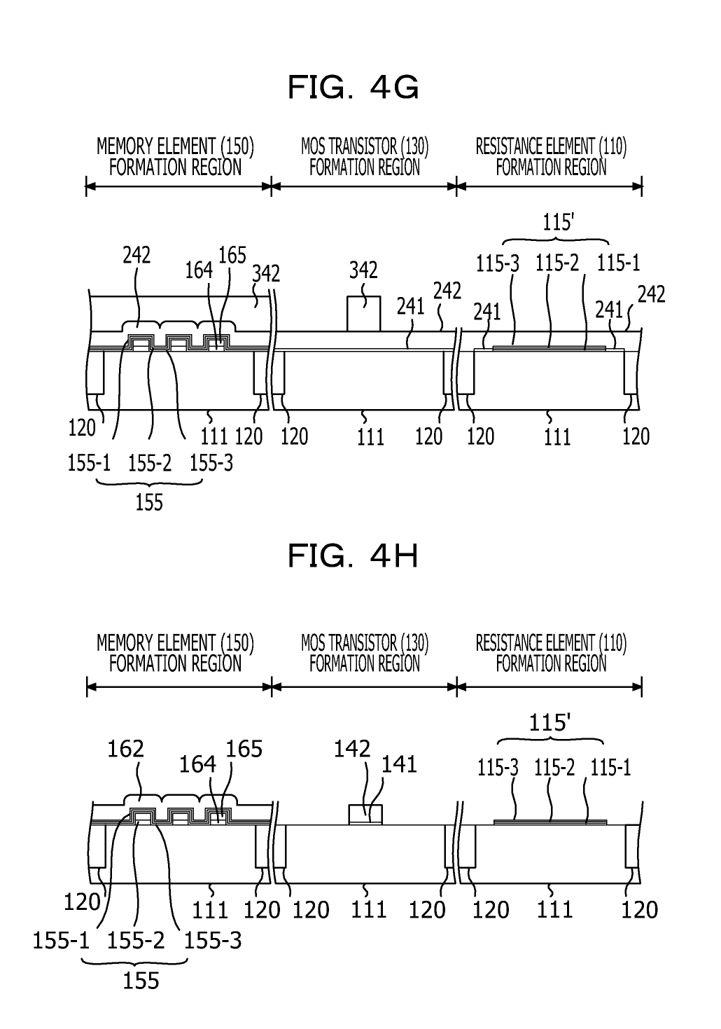

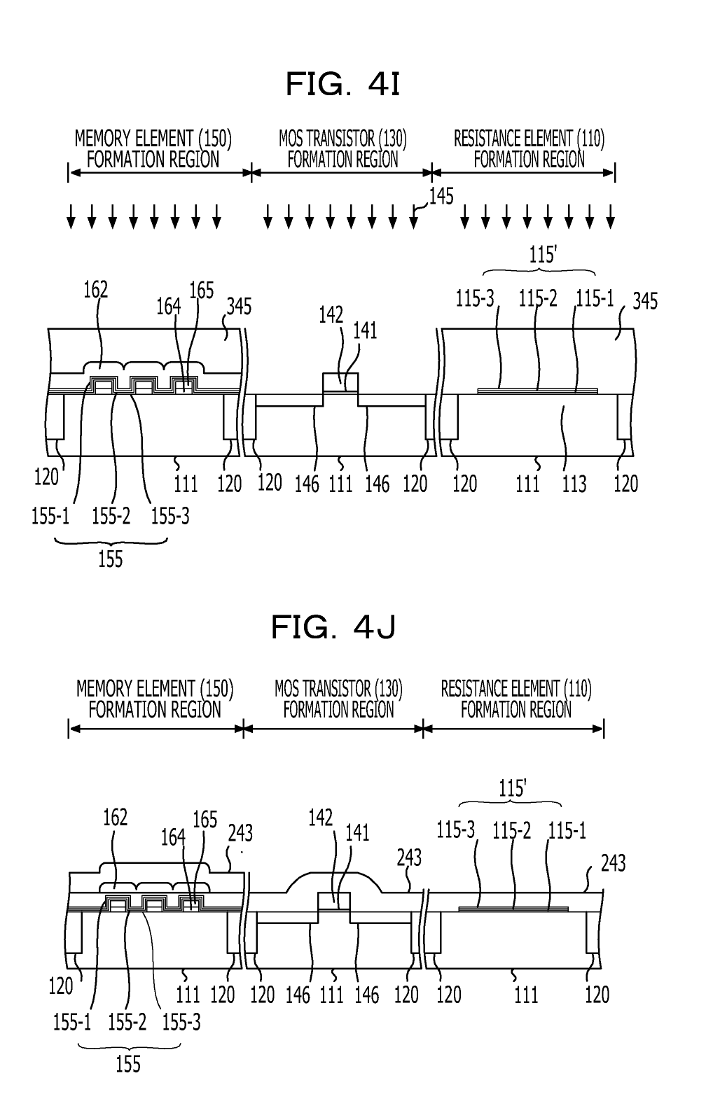

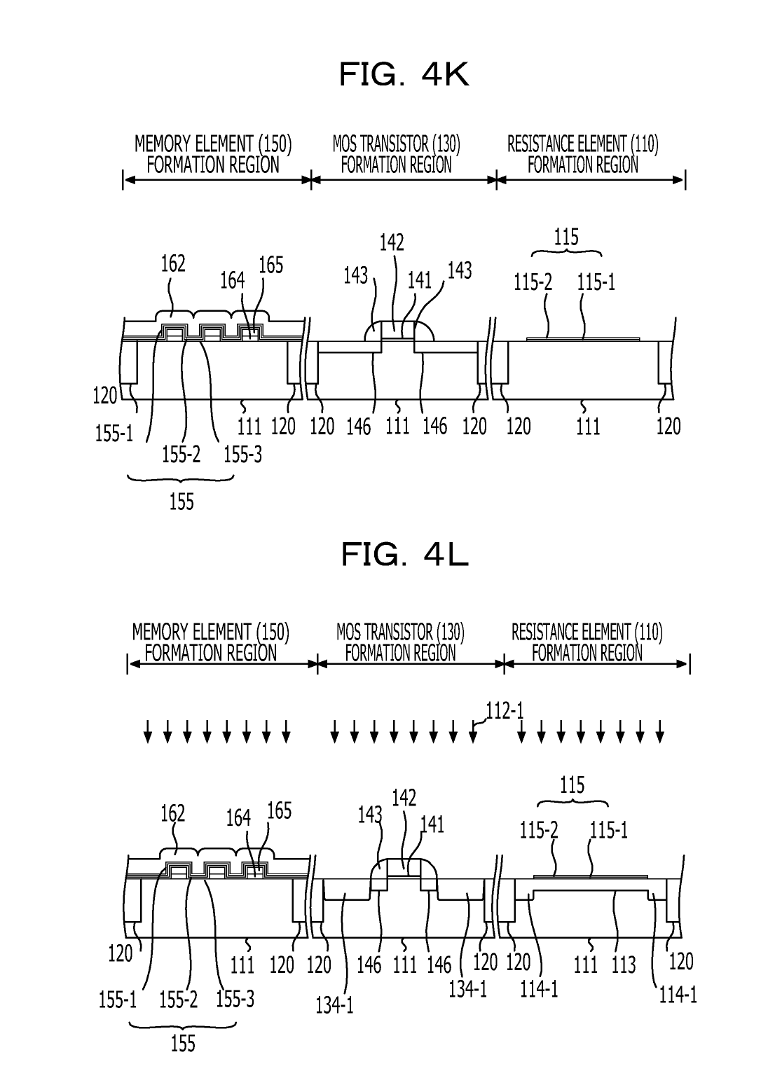

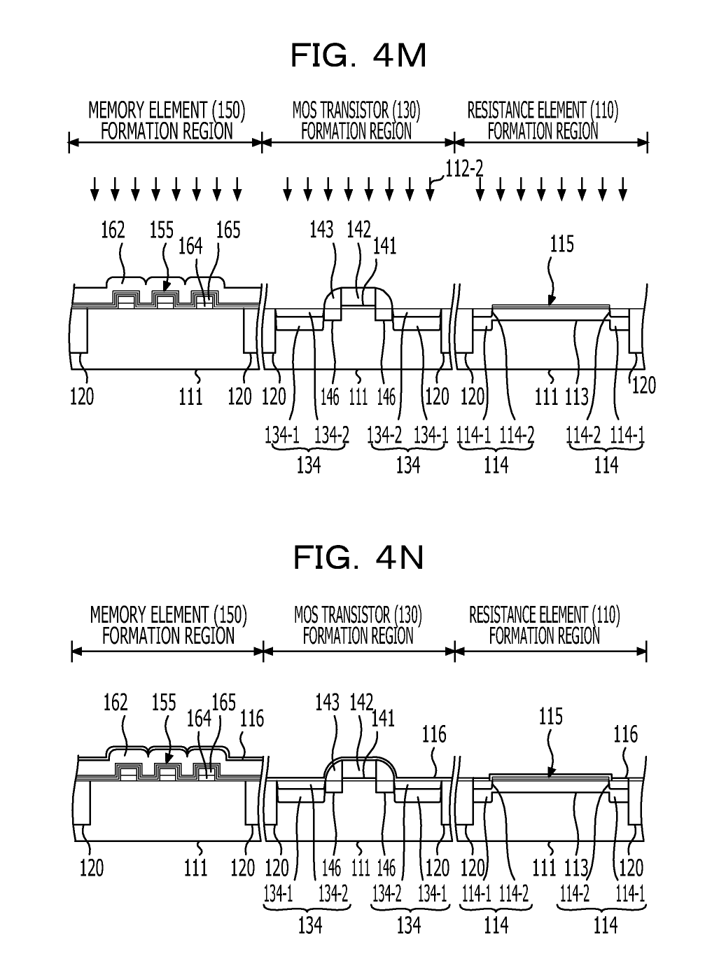

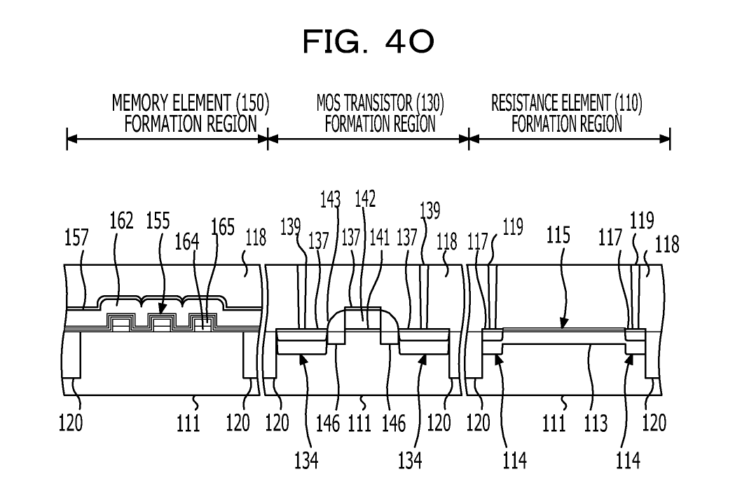

A method for manufacturing the semiconductor device illustrated in FIG. 3 will now be described with reference to FIGS. 4A to 4O. FIGS. 4A to 4O illustrate sectional structures of the semiconductor device in principal manufacturing steps, the sectional structures being each separated into three regions, namely a resistance element formation region, a MOS transistor formation region, and a memory element formation region.

As illustrated in FIG. 4A, an element-separating insulating film 120 is formed on a semiconductor substrate 111, which is a Si wafer or the like. For example, a shallow trench isolation (STI) structure is formed by forming a trench through etching, forming an insulating film made of silicon oxide or the like through chemical-vapor deposition (CVD), and performing planarization through chemical-mechanical polishing (CMP). The element-separating insulating film 120 may be an insulating film formed by local oxidation of silicon (LOCOS).

As illustrated in FIG. 4B, a tunnel insulating film 164 and a floating gate 165 are formed in a memory element formation region. For example, they are formed by forming a thermal oxidation film through thermal oxidation of the Si wafer 111, forming a first polysilicon film through CVD, and selectively removing the first polysilicon film and the thermal oxidation film through photolithography and etching.

As illustrated in FIG. 4C, an insulating film 215 is formed on the entire Si wafer 111. The insulating film 215 preferably includes a silicon nitride film that has resistance to etching of the polysilicon film and the silicon oxide film performed later. When a floating gate type memory element such as a flash memory is provided as in this embodiment, the insulating film 215 is preferably an ONO film including a silicon oxide film 215-1, a silicon nitride film 215-2, and a silicon oxide film 215-3. For example, the silicon oxide film 215-1 has a thickness of 9 to 14 nm, the silicon nitride film 215-2 has a thickness of 3 to 7 nm, and the silicon oxide film 215-3 has a thickness of 3 to 10 nm.

As illustrated in FIG. 4D, a photoresist mask 315 is formed in the memory element formation region and part of a resistance element formation region. Herein, for the semiconductor device including a floating gate type memory element, a photoresist mask in a memory element formation region is usually formed. Therefore, this step does not require an additional masking step of patterning a resistance element formation region.

As illustrated in FIG. 4E, a portion of the insulating film 215 not covered with the photoresist mask 315 is removed by etching, and the photoresist mask 315 is then removed. The insulating film 215 left in the memory element formation region serves as an intergate insulating film 155 of the memory element 150 and the insulating film 215 left in the resistance element formation region serves as an insulating film 115′ of the resistance element 110.

As illustrated in FIG. 4F, an insulating film 241 such as an oxide film is formed on a surface of the Si wafer 111 that is exposed in the MOS transistor formation region and the resistance element formation region, and a conductive film 242 is formed on the entire Si wafer 111. For example, a thermal oxidation film is formed as the insulating film 241 by thermal oxidation, and a second polysilicon film is formed as the conductive film 242 by CVD. The conductive film 242 is not limited to a polysilicon film, and may be, for example, a metal film.

As illustrated in FIG. 4G, a photoresist mask 342 is formed in the memory element formation region and part of the MOS transistor formation region.

As illustrated in FIG. 4H, portions of the conductive film 242 and the insulating film 241 not covered with the photoresist mask 342 are removed by etching, and the photoresist mask 342 is then removed. The conductive film 242 left in the memory element formation region serves as a control gate 162 of the memory element 150, and the conductive film 242 left in the MOS transistor formation region serves as a gate electrode 142 of the MOS transistor 130. A gate insulating film 141 is also formed below the gate electrode 142.

As illustrated in FIG. 4I, a photoresist mask 345 is formed in the memory element formation region and the resistance element formation region. An extension region 146 of the MOS transistor 130 is formed by performing ion implantation 145 and then heat treatment. In the MOS transistor formation region, the ion implantation 145 is performed by implanting an impurity into the extension region 146 using the gate electrode 142 as a mask. When the MOS transistor 130 is an NMOS transistor, the ion implantation 145 is performed by, for example, implanting arsenic at an energy of 5 keV and a dosage of 1.2×10¹⁵ cm⁻². When the MOS transistor 130 is a PMOS transistor, the ion implantation 145 is performed by, for example, implanting boron at an energy of 0.6 keV and a dosage of 1.2×10¹⁵ cm⁻².

An impurity may be optionally implanted into the resistance element 110 without forming the photoresist mask 345 in the resistance element formation region. However, the impurity dosage and acceleration energy in the ion implantation 145 are determined such that the extension region 146 has an electric-field-relaxation function, which means that the degree of freedom is low. Thus, even if an impurity is implanted into the resistance element 110 by performing ion implantation 145, the contribution of the ion implantation 145 to a resistance value of the resistance element 110 is restrictive.

As illustrated in FIG. 43, after the removal of the photoresist mask 345, a spacer insulating film 243 is formed on the entire Si wafer 111 by CVD or the like. The spacer insulating film 243 may be, for example, a silicon oxide film.

As illustrated in FIG. 4K, a side wall 143 is formed by leaving the spacer insulating film 243 on the side of the gate electrode 142 of the MOS transistor 130 by anisotropic etching or the like. Herein, there is no need to leave the spacer insulating film 243 in the resistance element formation region, which means that a masking step is unnecessary. Furthermore, when the spacer insulating film 243 is a silicon oxide film and the insulating film 115′ in the resistance element formation region includes a silicon nitride film, the silicon nitride film functions as an etching stop layer, which allows at least part (to be an insulating film 115) of the insulating film 115′ to be left with certainty. Therefore, when the insulating film 115′ in the resistance element formation region includes a material different from that of the spacer insulating film 243, it is possible to control the thickness of the insulating film 115 obtained after the step of etching the spacer insulating film 243. For example, assuming that the insulating film 115′ is an ONO film including a silicon oxide film 115-1, a silicon nitride film 115-2, and a silicon oxide film 115-3 as described in the drawing and the spacer insulating film 243 is a silicon oxide film, an insulating film 115 including the silicon oxide film 115-1 and the silicon nitride film 115-2 is left after the etching of the spacer insulating film 243.

As illustrated in FIG. 4L, ion implantation 112-1 is performed to form a first source/drain region 134-1 of the MOS transistor 130. During the ion implantation 112-1, ion implantation is simultaneously performed on a resistive layer 113 and an electrode layer 114-1 in the resistance element formation region.

As described in the first embodiment, the insulating film 115 determines the depth to which an impurity is implanted in the Si wafer 111 during the ion implantation 112-1. At the same time when the electrode layer 114-1 is formed, the insulating film 115 allows the resistive layer 113 to be formed directly below the insulating film 115 at a position shallower than that of the electrode layer 114-1.

The impurity concentration of the first source/drain region 134-1 of the MOS transistor has a degree of freedom higher than those of the impurity concentrations of the extension region 146 and a second source/drain region 134-2 (refer to FIG. 4M). Thus, when the ion implantation 112-1 is used for the ion implantation for the resistive layer 113 using the dosage as a parameter, the range of choices of a resistance value of the resistive layer 113 obtained is extended. For example, when an NMOS transistor 130 and an n-type diffusion resistance element 110 are formed, the ion implantation 112-1 may be performed by implanting phosphorus at an energy of 15 keV and a dosage of 1.0×10¹³ cm⁻² to 8.0×10¹³ cm⁻². The dosage range achieves a sheet resistance of 200 Ω/sq to 800 Ω/sq when the insulating film 115 includes a silicon oxide film 115-1 with a thickness of 11.5 nm and a silicon nitride film 115-2 with a thickness of 5 nm. When a PMOS transistor 130 and a p-type diffusion resistance element 110 are formed, the ion implantation 112-1 may be performed by implanting boron at an energy of 8 keV and a dosage of 7.0×10¹² cm⁻² to 9.0×10¹³ cm⁻². The dosage range achieves a sheet resistance of 300 Ω/sq to 900 Ω/sq when the insulating film 115 includes a silicon oxide film 115-1 with a thickness of 11.5 nm and a silicon nitride film 115-2 with a thickness of 5 nm.

As illustrated in FIG. 4M, ion implantation 112-2 is performed to form a second source/drain region 134-2 of the MOS transistor 130. During the ion implantation 112-2, ion implantation is simultaneously performed on an electrode layer 114-2 in the resistance element formation region.

For example, when an NMOS transistor 130 and an n-type diffusion resistance element 110 are formed, the ion implantation 112-2 may be performed by implanting phosphorus at an energy of 8 keV and a dosage of 1.2×10¹⁶ cm⁻². When a PMOS transistor 130 and a p-type diffusion resistance element 110 are formed, the ion implantation 112-2 may be performed by implanting boron at an energy of 4 keV and a dosage of 6.0×10¹⁵ cm⁻².

As described in the first embodiment, the insulating film 115 functions as a mask that prevents an impurity from being implanted into the resistive layer 113. In the ion implantation 112-2, part of the impurity may be optionally implanted into the resistive layer 113. The ion implantation 112-2 is preferred to independently control the sheet resistance of the resistive layer 113 and the characteristics, such as low resistivity, of the electrode region 114 and the source/drain region 134 of the MOS transistor, but may be omitted. Furthermore, the electrode region 114 of the resistance element 110 and the source/drain region 134 of the MOS transistor may each include three layers or more using an additional ion implantation step.

Heat treatment for activating the impurities implanted through the ion implantations 112-1 and 112-2 is performed, for example, after the ion implantation 112-2. This heat treatment may also serve as heat treatment performed after the ion implantation 145 for forming the extension region 146 illustrated in FIG. 4I.

As illustrated in FIG. 4N, a metal film 116 made of a high-melting point metal such as cobalt, titanium, or tungsten is formed on the entire Si wafer 111 by sputtering or the like.

As illustrated in FIG. 4O, heat treatment is performed, for example, in a nitrogen atmosphere, whereby a silicidation reaction is caused between the exposed Si wafer and semiconductor film and the metal film 116 to form a silicide film 117 in a self-aligning manner. As a result, the silicide film 117 is formed on a surface of the electrode region 114 of the resistance element 110, the silicide film 137 is formed on surfaces of the source/drain region 134 and the gate electrode 142 of the MOS transistor 130, and the silicide film 157 is formed on a surface of the control gate 162 of the memory element 150. Herein, the resistive layer 113 of the resistance element 110 is not silicided because it is covered with the insulating film 115, and thus the resistance is not decreased. Subsequently, by removing an unreacted metal film 116, forming an interlayer insulating film 118, patterning the interlayer insulating film 118, and embedding an electrode contact 119 and a source/drain contact 139, a structure of the semiconductor device illustrated in FIG. 3 is obtained.

In the second embodiment, the insulating film 115 is formed before the ion implantation step of forming the resistive layer 113. The ion implantation 112 (112-1 and 112-2) for forming the source/drain region 134 of the MOS transistor 130 may be used as the ion implantation step. The ion implantation 112 for forming the source/drain region 134 has a high degree of freedom for element design in terms of energy and dosage compared with the ion implantation 145 for forming the extension region 146. Therefore, the range of choices of a resistance value of the resistive layer 113 is extended. The insulating film 115 controls the amount of an impurity implanted into the semiconductor substrate 111 through the ion implantation 112 in accordance with the thickness thereof. This further extends the range of choices of a resistance value of the resistance element 110. The insulating film 115 also functions as a silicide block for the resistive layer 113. As a result, there is no need to form an additional silicide block after the formation of the resistive layer 113. Thus, by forming the insulating film 115 using an existing insulating film such as the ONO film formed in the memory element 150 and using an existing masking step such as the masking step of the ONO film, the resistance element 110 is formed without performing any additional masking step.

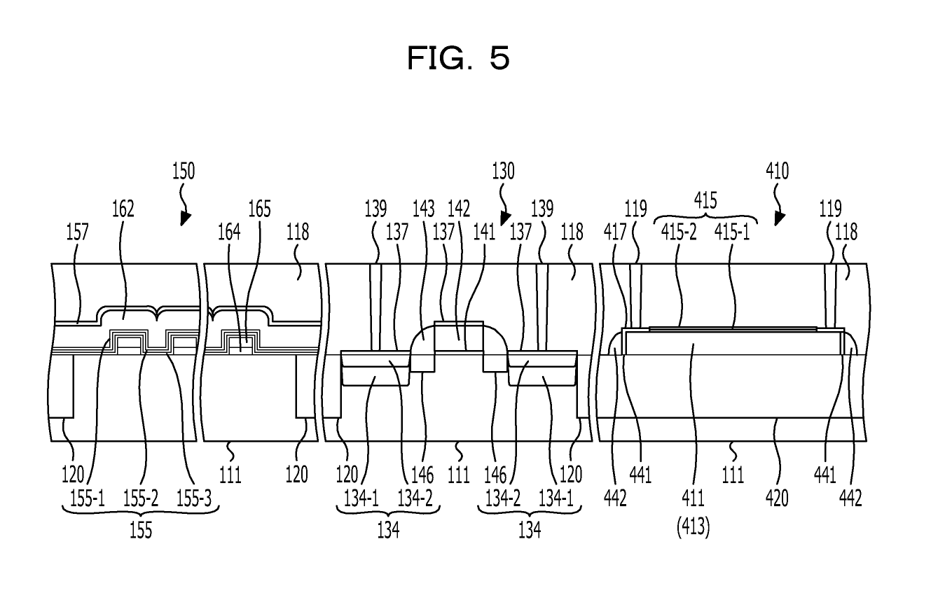

A semiconductor device according to a third embodiment will now be described with reference to FIG. 5. The described semiconductor device includes a resistance element 410, the MOS transistor 130, and the memory element 150. The MOS transistor 130 and the memory element 150 are the same as those included in the semiconductor device illustrated in FIG. 3. However, unlike the resistance element 110 of the semiconductor device illustrated in FIG. 3, the resistance element 410 is formed in a semiconductor film 411 formed on a Si wafer 111. Herein, the differences between the resistance element 410 and the resistance element 110 illustrated in FIG. 3 are described.

An element-separating insulating film 420 is formed in a resistance element (410) formation region so as to cover a surface of the Si wafer 111. The resistance element 410 includes a resistive layer 413, which is, for example, a doped polysilicon film. An insulating film 415 and a silicide film 417 are formed on an upper surface of the resistive layer 413. An oxide film 441 and a conductive film 442 are formed on the side of the resistive layer 413. The insulating film 415 includes a silicon oxide film 415-1 and a silicon nitride film 415-2 formed on the silicon oxide film 415-1 as in the insulating film 115 of the resistance element 110 illustrated in FIG. 3.

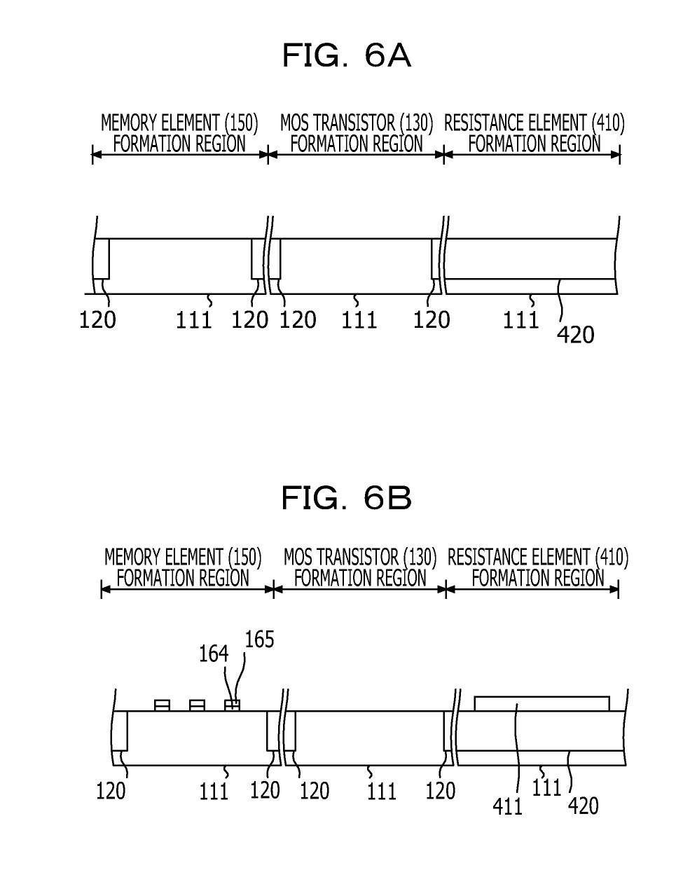

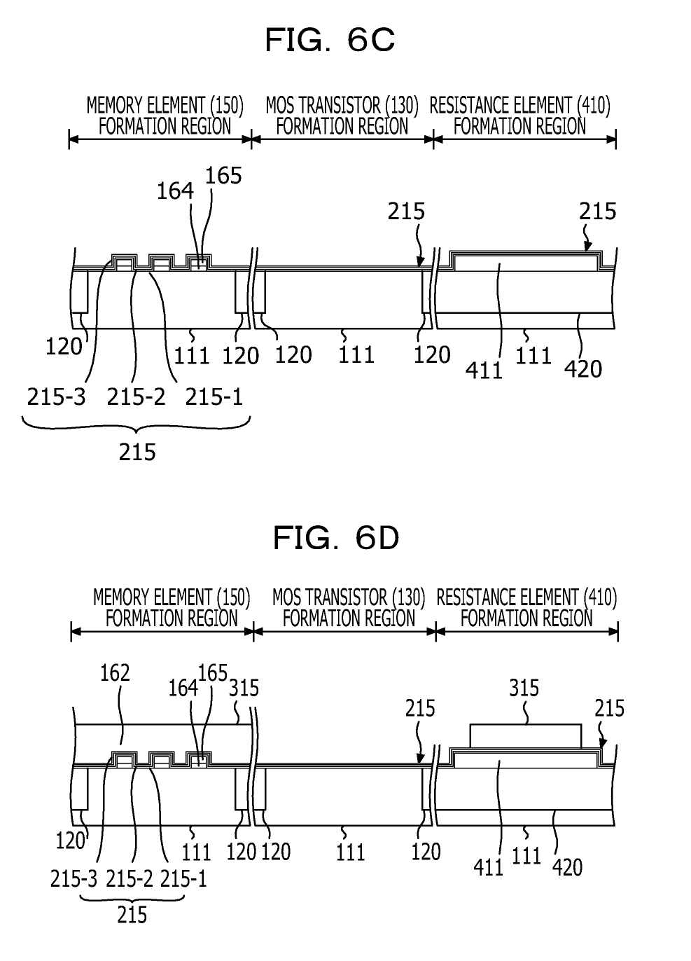

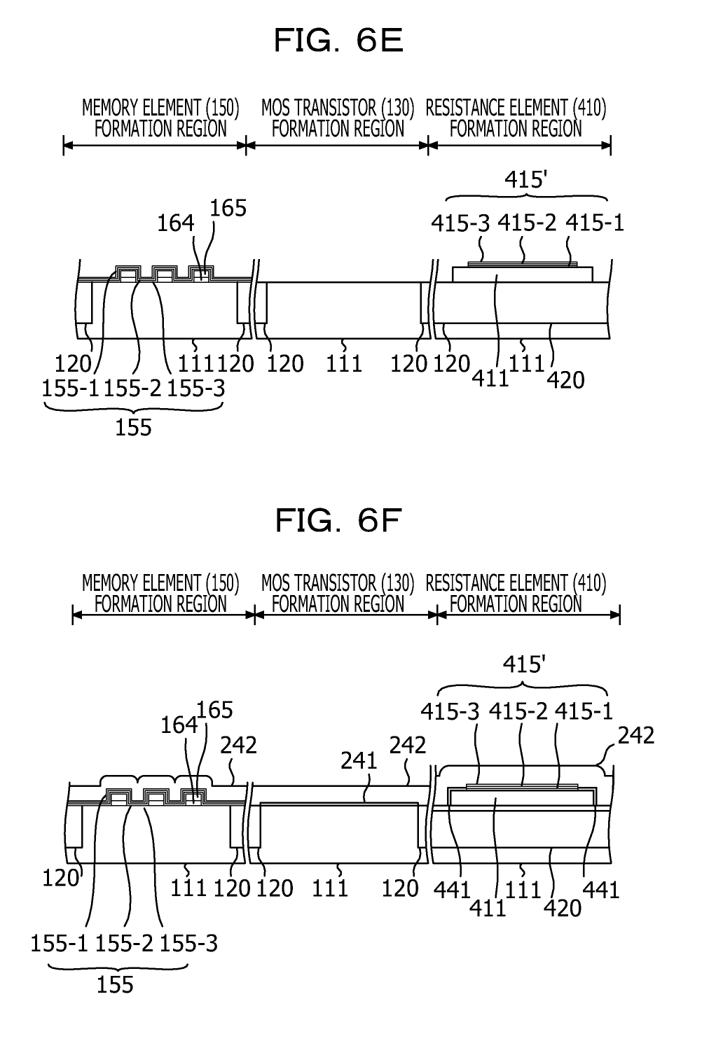

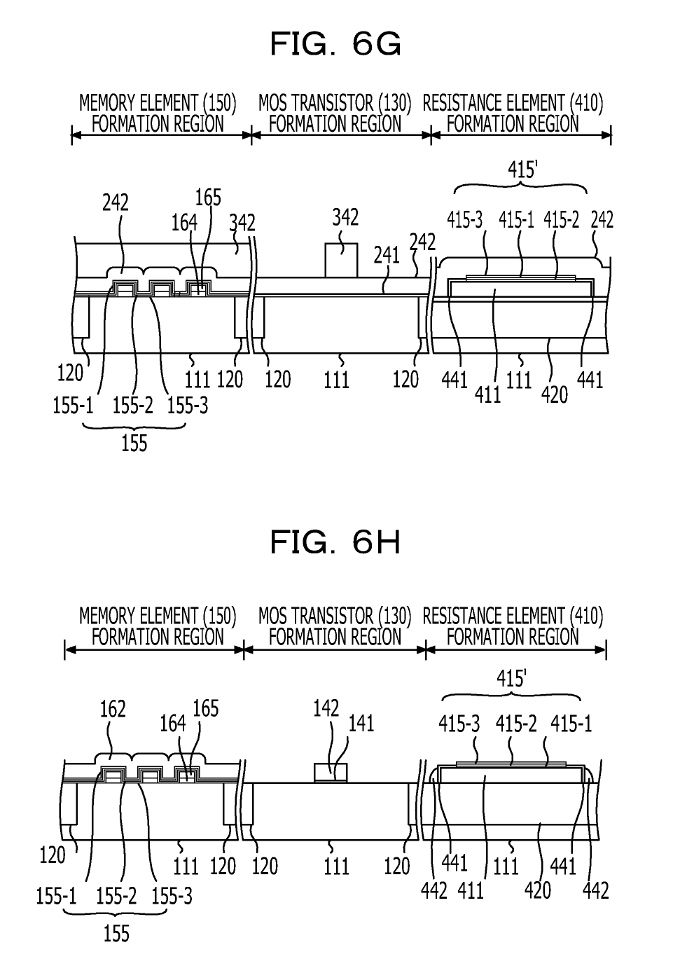

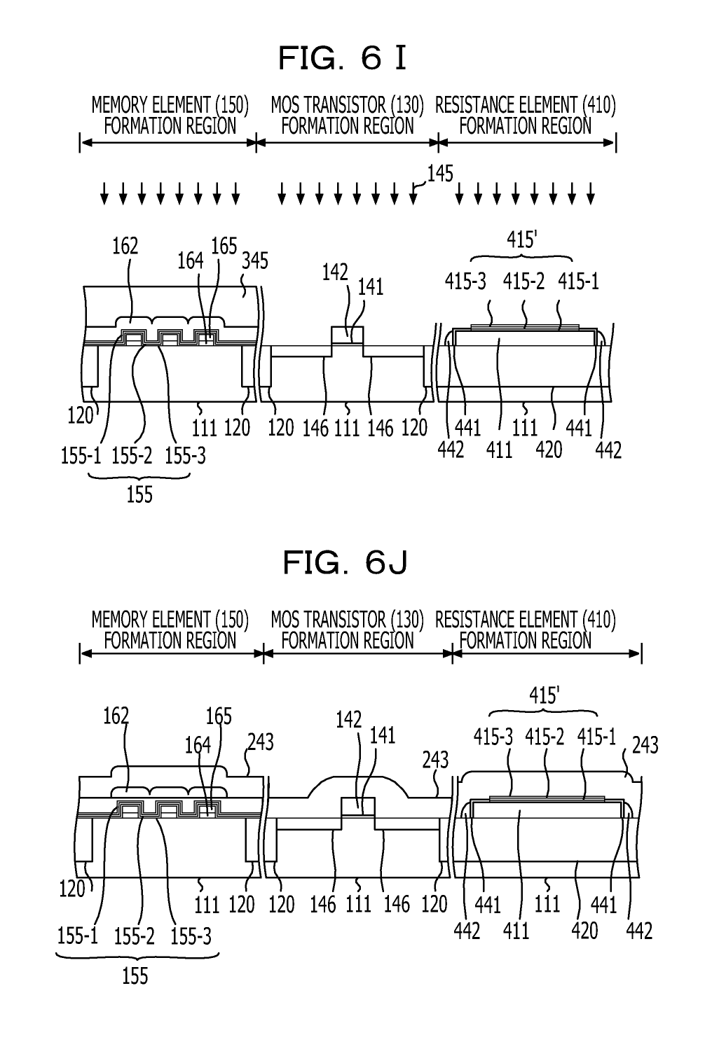

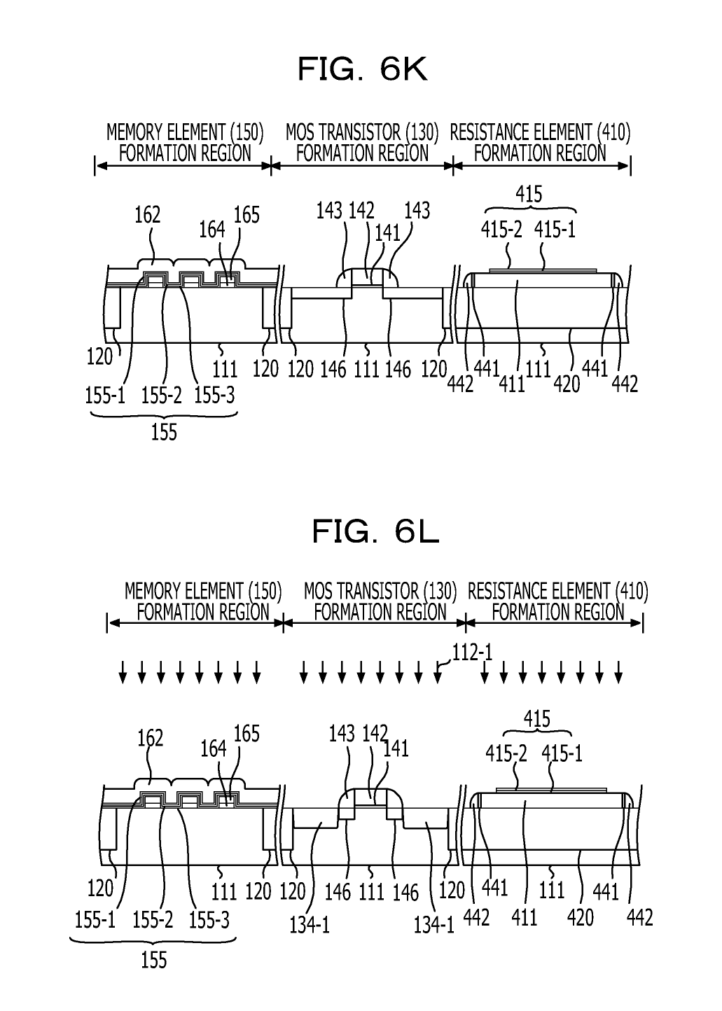

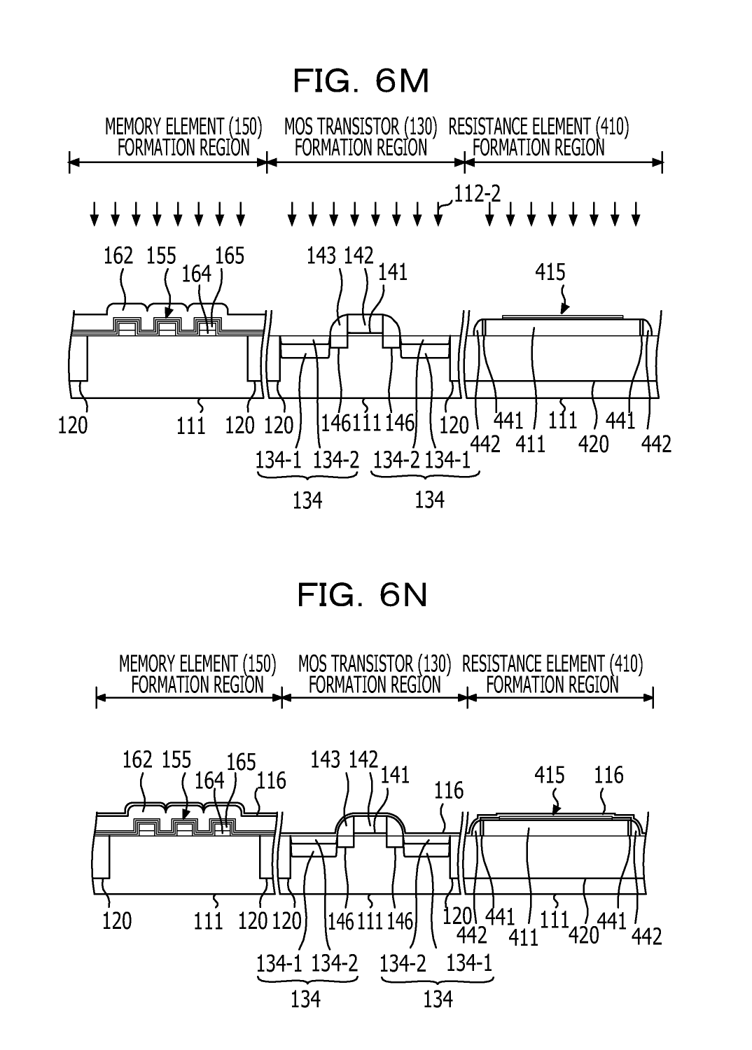

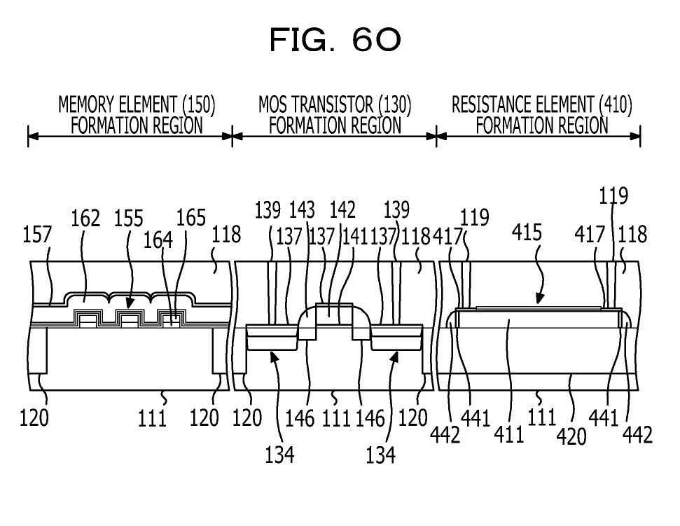

A method for manufacturing the semiconductor device illustrated in FIG. 5 will now be described with reference to FIGS. 6A to 6O. The steps illustrated in FIGS. 6A to 6O respectively correspond to the steps illustrated in FIGS. 4A to 4O that describe the method for manufacturing the semiconductor device illustrated in FIG. 3. Herein, the differences are mainly described.

As illustrated in FIG. 6A, an element-separating insulating film 120 of a MOS transistor formation region and a memory element formation region and an element-separating insulating film 420 of a resistance element formation region are formed on a surface of a Si wafer 111. The element-separating insulating film 420 is an insulating film formed by STI or LOCOS simultaneously together with the element-separating insulating film 120.

As illustrated in FIG. 6B, a tunnel insulating film 164 and a floating gate 165 are formed in the memory element formation region while a semiconductor film 411 is formed on the element-separating insulating film 420 in the resistance element formation region. The semiconductor film 411 and the floating gate 165 are simultaneously formed, and the semiconductor film 411 is formed of a first polysilicon film. At this stage, the semiconductor film 411 may be n-doped together with the floating gate 165.

As illustrated in FIG. 6C, an insulating film 215 is formed on the entire Si wafer 111. The insulating film 215 is preferably an ONO film including a silicon oxide film 215-1, a silicon nitride film 215-2, and a silicon oxide film 215-3.

As illustrated in FIG. 6D, a photoresist mask 315 is formed in the memory element formation region and part of the resistance element formation region.

As illustrated in FIG. 6E, a portion of the insulating film 215 not covered with the photoresist mask 315 is removed by etching, and the photoresist mask 315 is then removed. The insulating film 215 left on the semiconductor film 411 in the resistance element formation region serves as an insulating film 415′ of the resistance element 410.

As illustrated in FIG. 6F, an oxide film 241 is formed on a surface of the Si wafer 111 that is exposed in the MOS transistor formation region, and a conductive film 242 is formed on the entire Si wafer 111. For example, a thermal oxidation film is formed as the oxidation film 241 by thermal oxidation, and a second polysilicon film is formed as the conductive film 242 by CVD. An oxide film 441 is also formed on an exposed surface of the semiconductor film 411 in the resistance element formation region.

As illustrated in FIG. 6G, a photoresist mask 342 is formed in the memory element formation region and part of the MOS transistor formation region.

As illustrated in FIG. 6H, a portion of the conductive film 242 not covered with the photoresist mask 342 is removed by etching, and the photoresist mask 342 is then removed. After the etching, a conductive film 442 may be left on the side of the semiconductor film 411 of the resistance element 410.

As illustrated in FIG. 6I, a photoresist mask 345 is formed in the memory element formation region. An extension region 146 of the MOS transistor 130 is formed by performing ion implantation 145 and then heat treatment. A photoresist mask may be optionally formed in the resistance element formation region.

As illustrated in FIG. 6J, after the removal of the photoresist mask 345, a spacer insulating film 243 is formed on the entire Si wafer 111. The spacer insulating film 243 may be, for example, a silicon oxide film.

As illustrated in FIG. 6K, a side wall 143 is formed by leaving the spacer insulating film 243 on the side of the gate electrode 142 of the MOS transistor 130 by anisotropic etching or the like. Herein, there is no need to leave the spacer insulating film 243 in the resistance element formation region, which means that a masking step is unnecessary. Furthermore, when the spacer insulating film 243 is a silicon oxide film, the oxide film 441 formed on the semiconductor film 411 is also removed from the resistance element formation region. However, when the insulating film 415′ formed on the semiconductor film 411 includes a silicon nitride film, the silicon nitride film functions as an etching stop layer, which allows at least part (to be an insulating film 415) of the insulating film 415′ to be left with certainty. Therefore, when the insulating film 415′ includes a material different from that of the spacer insulating film 243, it is possible to control the thickness of the insulating film 415 obtained after the step of etching the spacer insulating film 243. For example, assuming that the insulating film 415′ is an ONO film including a silicon oxide film 415-1, a silicon nitride film 415-2, and a silicon oxide film 415-3 as described in the drawing and the spacer insulating film 243 is a silicon oxide film, an insulating film 415 including the silicon oxide film 415-1 and the silicon nitride film 415-2 is left after the etching of the spacer insulating film 243.

As illustrated in FIG. 6L, ion implantation 112-1 is performed to form a first source/drain region 134-1 of the MOS transistor 130. During the ion implantation 112-1, ion implantation is simultaneously performed on semiconductor film 411 in the resistance element formation region. Herein, the insulating film 415 controls the depth to which an impurity is implanted in the semiconductor film 411 during the ion implantation 112-1.

If the semiconductor film 411 is n-doped in the step illustrated in FIG. 6B, the ion implantation 112-1 may be used as ion implantation for a source/drain region 134 of a PMOS transistor 130, and a p-type impurity such as boron may be counter-doped in the semiconductor film 411.

As illustrated in FIG. 6M, ion implantation 112-2 is performed to form a second source/drain region 134-2 of the MOS transistor 130. During the ion implantation 112-2, ion implantation is simultaneously performed on the semiconductor film 411 in at least an area of the resistance element formation region where the insulating film 415 is not present.

As illustrated in FIG. 6N, a metal film 116 made of a high-melting point metal is formed on the entire Si wafer 111.

As illustrated in FIG. 6O, by performing heat treatment, a silicidation reaction is caused between the exposed Si wafer and semiconductor film and the metal film 116 to form a silicide film in a self-aligning manner. As a result, the silicide film 417 is formed in a region located outside the insulating film 415 and on the semiconductor film 411 of the resistance element 410, the silicide film 137 is formed on surfaces of the source/drain region 134 and the gate electrode 142 of the MOS transistor 130, and the silicide film 157 is formed on a surface of the control gate 162 of the memory element 150. Herein, a portion of the semiconductor film 411 covered with the insulating film 415 is not silicided, and thus the resistance is not decreased. Subsequently, by removing an unreacted metal film 116, forming an interlayer insulating film 118, patterning the interlayer insulating film 118, and embedding an electrode contact 119 and a source/drain contact 139, a structure of the semiconductor device illustrated in FIG. 5 is obtained.

In the semiconductor device and the method for manufacturing the semiconductor device according to the third embodiment, it is also possible to extend the range of choices of a resistance value of the resistance element using existing structural elements and steps in the same manner as in the second embodiment.

The resistance element 110 described in the second embodiment and the resistance element 410 described in the third embodiment may be simultaneously formed on the same semiconductor substrate.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that various changes, substitutions, and alterations could be made hereto without departing from the spirit and scope of the invention.

What is claimed is:

1. A method for manufacturing a semiconductor device comprising:
forming an insulating film on a semiconductor region of a semiconductor substrate on which a MOS transistor is to be formed and patterning the insulating film;
implanting an impurity into the semiconductor region through the patterned insulating film using a step of implanting an impurity into a source/drain region of the MOS transistor, to form, below the insulating film, a resistive layer of a resistance element in the semiconductor region; and
siliciding a surface of the source/drain region of the MOS transistor using the insulating film as a silicidation-preventing film of the resistive layer.

2. The method according to claim 1,
wherein the insulating film includes a silicon nitride film.

3. The method according to claim 1,
wherein the insulating film is a stacked insulating film including a silicon oxide film and a silicon nitride film.

4. The method according to claim 1,
wherein, implanting the impurity into the semiconductor region includes a first ion implantation performed at a first energy and a second ion implantation performed at a second energy lower than the first energy.

5. The method according to claim 4,
wherein, in the first ion implantation, an impurity is implanted into the resistive layer, and
in the second ion implantation, an impurity is not implanted into the resistive layer.

6. The method according to claim 4,
wherein, in the first ion implantation, phosphorus is implanted at a dosage of 1.0×10¹³ cm⁻² to 8.0×10¹³ cm⁻² or boron is implanted at a dosage of 7.0×10¹² cm⁻² to 9.0×10¹³ cm⁻².

7. The method according to claim 1,
wherein, in implanting the impurity into the semiconductor region, an electrode region of the resistance element is formed so as to be adjacent to the resistive layer, and
in siliciding the surface of the source/drain region, a surface of the electrode region is silicided.

8. The method according to claim 1, further comprising, between the step of forming the insulating film on the semiconductor region and the implanting the impurity into the semiconductor region:
forming a gate electrode of the MOS transistor; and
an additional implantation of implanting an impurity using the gate electrode as a mask to form an extension region of the MOS transistor.

9. The method according to claim 8,
wherein the additional implantation is performed at a third energy without implanting an impurity into the resistive layer.

10. The method according to claim 8, further comprising, after the additional implantation:
forming a side wall on a side of the gate electrode,
wherein the insulating film is made of a material different from that of the side wall.

11. The method according to claim 1,
wherein the semiconductor device further includes a memory element having a floating gate and a control gate, and
in forming the insulating film on a semiconductor region, the insulating film is also formed on the floating gate.

12. The method according to claim 1, further comprising, before forming the insulating film on a semiconductor region:
forming a polysilicon film on the semiconductor substrate,
wherein the semiconductor region is a region located in the polysilicon film.

13. A semiconductor device comprising:
a resistive layer;
an electrode region adjacent to the resistive layer;
an insulating film located on the resistive layer; and
a silicide film formed on a surface of the electrode region,
wherein the resistive layer and the electrode region each have a semiconductor region into which an impurity is implanted through ion implantation, and
a depth of the resistive layer is lower than that of the electrode region, the depth of the resistive layer being determined in accordance with a thickness of the insulating film during the ion implantation.

14. The semiconductor device according to claim 13,
wherein the insulating film is a stacked insulating film including a silicon oxide film and a silicon nitride film.

15. The semiconductor device according to claim 13, further comprising:
a MOS transistor,
wherein a source/drain region of the MOS transistor has the same depth as that of the electrode region.

16. The semiconductor device according to claim 15,
wherein the MOS transistor includes the silicide film on a surface of the source/drain region, and
the silicide film includes a high-melting point metal.

17. The semiconductor device according to claim 15,
wherein the MOS transistor includes a side wall formed on a side of a gate electrode, and
the insulating film is made of a material different from that of the side wall.

18. The semiconductor device according to claim 13, further comprising:
a memory element;
wherein the memory element includes a floating gate, the insulating film including a silicon oxide film formed on the floating gate and a silicon nitride film formed on the silicon oxide film, and a control gate formed on the insulating film.

19. The semiconductor device according to claim 13,
wherein the resistive layer and the electrode region are formed in a semiconductor substrate.

20. The semiconductor device according to claim 13,
wherein the resistive layer and the electrode region are formed in a semiconductor film formed on a semiconductor substrate.
